(19) United States
(12) Patent Application Publication
(10) Pub. No.: US 2026/0223334 A1
(43) Pub. Date: Jul. 30, 2026

(54) EXPANSION COOLING SYSTEM

(71) Applicant: R7 Instruments, Inc., Somerville, MA (US)

(72) Inventors: Jacob Adams, Somerville, MA (US); Carl Bunge, Somerville, MA (US)

(21) Appl. No.: 19/465,476

(22) Filed: Jan. 30, 2026

Related U.S. Application Data
(60) Provisional application No. 63/751,709, filed on Jan. 30, 2025.

(51) Int. Cl. H05K 7/20

(52) U.S. Cl. CPC H05K 7/20827; H05K 7/20327; H05K 7/20354; H05K 7/20372

(57) ABSTRACT

A distributed cryogenic cooling system for computational facilities includes multiple insulated housings containing computational components requiring cryogenic temperatures. Each housing receives ambient-temperature, high-pressure fluid through facility supply lines and returns low-pressure fluid through facility return lines. A shared compression system circulates working fluid throughout the facility. Within each housing, energy-extracting fluid expanders mounted on the housing produce local refrigeration by expanding fluid from high to low pressure, transferring extracted energy outside the housing. An internal fluid bus routes cooled fluid from the expanders to component heat exchangers thermally coupled to computational components. This architecture eliminates vacuum-insulated transfer lines, avoids single-point-of-failure by distributing cooling capability, reduces working fluid inventory, and enables modular repairs of individual housings without system shutdown while maintaining efficient cryogenic cooling for large-scale quantum computers, superconducting circuits, and similar computational systems.

### CROSS-REFERENCE TO RELATED APPLICATIONS

This application claims the benefit of U.S. Provisional Application No. 63/751,709, filed Jan. 30, 2025, which is incorporated herein by reference in its entirety.

### FIELD OF TECHNOLOGY

The disclosed subject matter relates to a computation facility that requires cryogenic cooling.

### BACKGROUND

The advent of cryogenic computers, like superconducting digital circuits and quantum computers require cryogenic cooling systems. As these cryogenic computers grow larger in scale, a distributed cryogenic cooling system is needed to hold each server rack at cryogenic temperature and maintain modularity with the ability to complete repairs on individual racks without compete system shutdown. This invention provides a method for large-scale, low-cost distributed cooling of several cryogenic server racks, with a centralized compression system and distributed at-rack cooling systems.

In many existing large-scale cryogenic computer systems, a centralized expansion cooling system is used to liquefy a working fluid to cryogenic temperatures. This working fluid is often helium for applications requiring temperatures below 20 Kelvin (K). These centralized expansion cooling systems will be referred to as liquefiers. These liquefiers are based on the Claude or Collins cycle. In the liquefier configuration, the refrigerated liquid is transferred via vacuum insulated transfer lines to the cryogenic computers that are located a distance away from the centralized helium liquefier. Without these vacuum insulated transfer lines, the cryogenic liquid would absorb an excessive amount of heat from the ambient environment. The vacuum insulated transfer lines incur a large capital cost and require cryogenic liquid control valves to meter the rate of liquid flow. There is a need for a large-scale cryogenic cooling system for cryogenic computers that does not require complex and costly vacuum insulated transfer lines with their associated infrastructure.

Another challenge with the liquefier cooling systems is the reliance on the single-point-of-failure liquefier system itself. If the liquefier system is damaged or inoperable, then cooling is halted at all of the cryogenic server racks. It is the objective of the present invention to provide a distributed expansion cooling system without a single-point-of-failure.

Another challenge with liquefier cooling systems is the need for a large quantity of cryogenic fluid throughout the system. This cryogenic fluid is stored in a vacuum insulated dewar to minimize ambient heat leak. In the case of a cryogenic computer with helium as the working fluid, this large quantity of helium is expensive, and, if there is a power outage with the liquefier inoperable, this helium needs to be vented or collected in large volume gas bag or container. It is the objective of the present invention to provide a distributed cryogenic cooling system without the need for a large quantity of liquid helium.

There exist other methods in the art to provide cryogenic cooling, beyond the Claude of Collins cycle described previously, known as regenerative cryocoolers or GM-cryocoolers or Stirling cryocoolers. A challenge with these regenerative cryocoolers is that they generally have low cooling powers below 20 K making these coolers unsuitable for the high cooling power requirements of a cryogenic data center. Furthermore, regenerative cryocoolers rely on conduction cooling, meaning that the computational components to be cooled must have a physical thermal link to the regenerative cryocooler. This thermal link may be, for example, a copper braid. Conduction cooling is inefficient when removing heat from a multitude of cryogenic computer processors over a large area. It is an objective of the present invention to provide for a cryogenic cooling system wherein the cooled working fluid may be distributed throughout a fluid bus internal to the insulated server rack to each of the computational components within. The working fluid is cooled by an energy extracting fluid expander.

Another challenge with existing cryogenic cooling systems based on the regenerative cryocooler architecture is the low efficiency at temperatures below 20 K. It is an objective of the present invention to provide for a distributed cryogenic cooling system where recuperative heat exchangers can be used for refrigeration below 20 K. Regenerative cryocoolers may still be used as a pre-cooling stage at temperatures above approximately 20 K.

### BRIEF SUMMARY

This invention is a computational facility cooling architecture where the computational components require cooling to cryogenic temperatures. This architecture allows for a distributed cryogenic cooling system without a single point of failure. In this facility, there are several insulated housings with computational components therein. These insulated housings may also be called server racks. Each insulated housing is provided with a set of facility high pressure fluid supply lines and a set of facility low pressure fluid return lines. The set of facility fluid supply lines and facility fluid return lines are at a temperature that is near ambient temperature. A set of fluid compressors is used to circulate the working fluid throughout the facility fluid supply lines and facility fluid return lines to each of the insulated housings. Within each of the insulated housings is a fluid bus that is fluidically coupled to energy extracting fluid expanders. The fluid expanders produce refrigeration locally within the insulated housing from the expansion of the working fluid from high pressure to low pressure. The energy extracted from these expansion processes is transferred outside of the insulated housing to the ambient environment. The cold working fluid from the fluid expanders is routed via the internal fluid bus to the computational components to remove heat from these components.

This facility offers several novel advantages over existing centralized helium liquefier systems in the application of large scale cryogenic computers. A first advantage is the near ambient facility supply lines to each of the insulated housings, as opposed to vacuum insulated transfer lines to each of the insulated housings. A second advantage is a distributed cooling system such that each of the insulated housings has its own cooling system while the facility shares a common compression system. In this distributed design, if a single fluid expander is inoperable, then only a single insulated housing is without cooling. A third advantage is that a much smaller quantity of working fluid, usually helium, is used in the cryogenic cooling system for the computational facility.

### BRIEF DESCRIPTION OF THE DRAWINGS

To easily identify the discussion of any particular element or act, the most significant digit or digits in a reference number refer to the figure number in which that element is first introduced.

FIG. 1 illustrates an embodiment of an expansion cooling system according to the disclosed subject matter.

FIG. 2 is a representation of an embodiment of an expansion cooling system, according to the disclosed subject matter.

FIG. 3 shows another embodiment of an expansion cooling system according to the disclosed subject matter.

FIG. 4 shows an embodiment of an expansion cooling system with dissipation component details according to the disclosed subject matter.

FIG. 5 is a further embodiment of an expansion cooling system with vibration isolation according to the disclosed subject matter.

FIG. 6 is another embodiment of an expansion cooling system with a regenerative cryocooler according to the disclosed subject matter.

FIG. 7 shows another embodiment of an expansion cooling system with dual fluids according to the disclosed subject matter.

FIG. 8 is an embodiment of several expansion cooling systems integrated into a facility as described according to the disclosed subject matter.

FIG. 9 is an embodiment of several expansion cooling systems integrated into a facility as described according to the disclosed subject matter.

### DETAILED DESCRIPTION

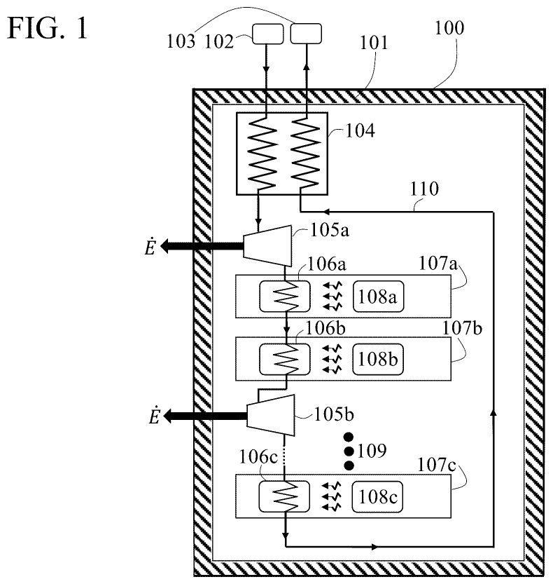

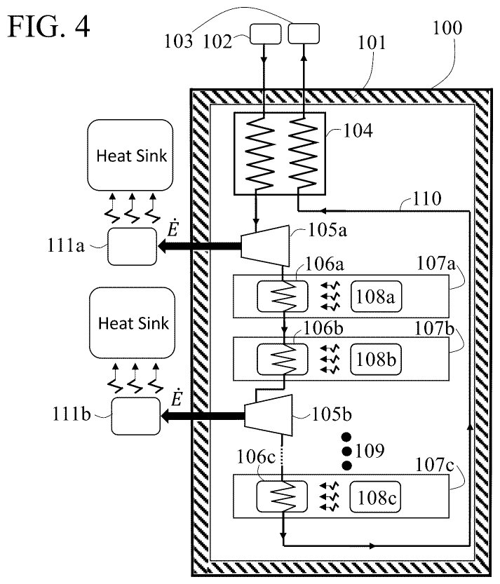

FIG. 1 illustrates a schematic drawing of one embodiment of an expansion cooling system. The cooling system is integrated into an insulated housing 100 with thermal insulation 101 to prevent ambient heat leak to the components within the insulated housing 100. The thermal insulation 100 may be a radiation shield or multi-layer insulation. The insulated housing interior may be filled or partially filled with a fluid, or be a complete or partial vacuum. A high-pressure, ambient-temperature fluid is supplied to inlet manifold 102. After the fluid has delivered cooling within the housing, it exits at outlet manifold 103 at low-pressure. Between the inlet manifold 102 and outlet manifold 103, a fluid bus 110 carries the fluid through several components and heat exchangers. The fluid bus 110 may be a series of tubes in parallel or series configuration and may have valves, regulators, and other related components. In the FIG. 1 embodiment, there is a recuperative heat exchanger 104 on the fluid bus 110 that precools the incoming high-pressure working fluid with the outgoing low-pressure working fluid. After this recuperative heat exchanger 104, the high-pressure working fluid travels along the fluid bus 110 to an energy extracting fluid expander 105a. Fluid expander 105a reduces the fluid pressure and extracts mechanical energy through this expansion process. The working fluid exits fluid expander 105a at a lower pressure and is cooled by this expansion process. The mechanical energy extracted from the working fluid exits the housing interior, where the expansion energy can be dissipated as heat to a heat sink (this embodiment is FIG. 4) or can be re-collected to drive a compression process or can be re-collected as electrical energy. After exiting the fluid expander 105a, the cold working fluid travels along the fluid bus 110 to a component heat exchanger 106a that is thermally coupled to the component module 107a. Component module 107a accommodates one or more computational components 108a that require cooling. Computational component 108a may be a computer processor, computer memory, quantum processor, superconducting processor, or other computational components that need to be held at cryogenic temperature. There can be multiple component modules 107 which accommodate the computational components 108 that need to be cooled. After leaving component heat exchanger 106a the intermediate pressure working fluid travels to component heat exchanger 106b that is thermally coupled to component module 107b. Component module 107b can accommodate computational component 108b. In this FIG. 1 embodiment, component heat exchanger 106a and 106b are in fluidic series and connected by fluid bus 110. The intermediate-pressure working fluid can then enter a second energy extracting fluid expander 105b that reduces the working fluid pressure and extracts mechanical energy through the expansion process. The working fluid that exits fluid expander 105b is at a low-pressure and is cooled by this expansion process. The mechanical energy extracted from the working fluid exits the housing interior, where the expansion energy can be dissipated as heat to an ambient heat sink (this embodiment is FIG. 4) or can be re-collected to drive a compression process or can be re-collected as electrical energy. After exiting the fluid expander 105b the cold working fluid travels along the fluid bus 110 to component heat exchanger 106c that is thermally coupled to the component module 107c. This configuration of fluid expanders 105, component heat exchangers 106, and component modules 107 can be repeated as denoted by enumeration 109.

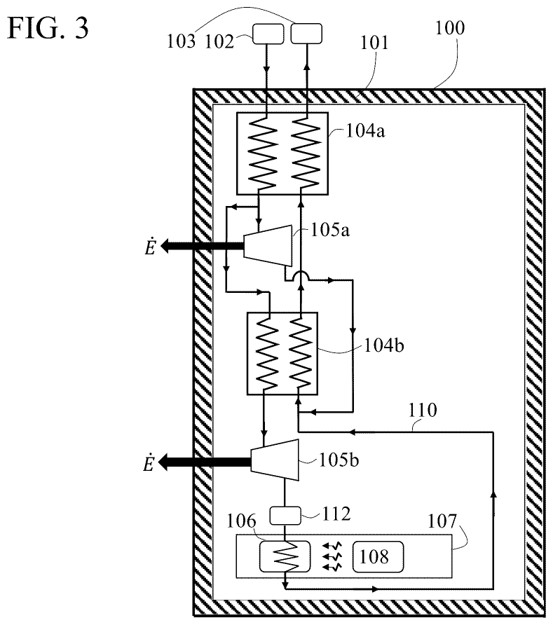

The energy extracting fluid expanders 105 may be constructed from a reciprocating piston device or a turbo-machine. The energy extracting fluid expanders may also use acoustic pressure waves to transfer energy from within the housing to outside of the housing. The purpose of these fluid expanders is to extract mechanical energy from the working fluid expansion process thereby cooling the working fluid as it expands. This is in contrast to a Joule-Thomson expansion or Joule-Thomson throttle which does not extract any mechanical energy from the expansion process and is hence significantly less efficient than the fluid expanders 105. Although Joule-Thomson throttles may also be used in parallel with the fluid expanders in some embodiments as seen in FIG. 3.

The cooling power at each of the component heat exchangers 106 is, in part, determined by the rate of fluid flow through the energy extracting fluid expanders 105 and the pressure drop across these fluid expanders. The rate of cooling power can be altered by modifying the working fluid flow and/or pressure drop across the fluid expanders. The rate of working fluid flow can be modulated by, for example, turning the fluid expanders on and off in a bang-bang control. Another method to control the cooling power is by modifying the frequency at which the fluid expanders operate and hence changes the rate of working fluid flow and/or the pressure drop across the fluid expanders.

The insulated housing 100 may have a door or other feature that allows for accessing the inside of the insulated housing, for example a port for servicing the computational components or fluid bus therein. The insulated housing 100 may be a cylindrical vessel with approximate dimensions of 1-10 meters in diameter and 1-10 meters in length. The insulated housing may also be a rectangular vessel with approximate dimensions of 1-10 meters on any given side length.

The energy extracting fluid expanders 105 may be on a removable flange that is mounted to the insulated housing 100. The expansion machines 105 may be located on the side of the insulated housing as seen in FIG. 1 or located on the top of the insulated housing or located on the bottom of the insulated housing.

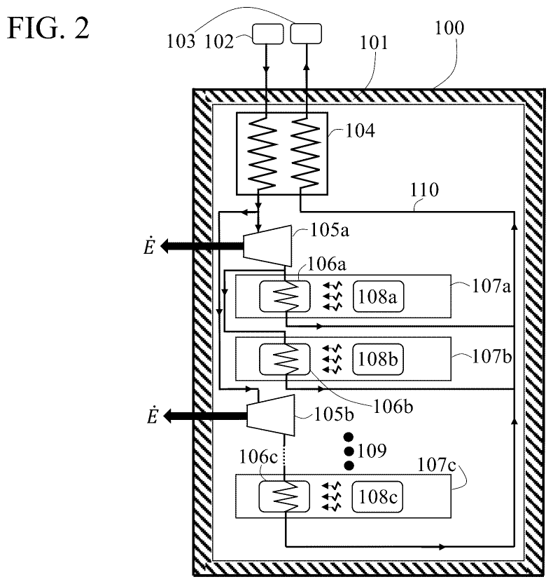

The specific design of the expansion cooling system depends on the configuration and desired cooling architecture. FIG. 1 shows the fluid expanders 105 in series with component heat exchangers 106 in between the fluid expanders. This arrangement may be beneficial to minimize entropy generation and improve the overall efficiency of the refrigeration cycle. It may also be advantageous to employ fluidic parallelization strategies as in FIG. 2 and FIG. 3. The low-pressure working fluid then travels along the fluid bus 110 back to recuperative heat exchanger 104 to precool the incoming high-pressure working fluid. The low-pressure working fluid exits the insulated housing to outlet manifold 103 at near ambient temperature.

FIG. 2 shows a schematic drawing of one embodiment of an expansion cooling system integrated into an insulated housing 100 that comprises thermal insulation 101 to prevent ambient heat leak into the components. This embodiment in FIG. 2 is similar to that shown in FIG. 1, however, the fluid expanders 105a and 105b are arranged fluidically in parallel as opposed to series as in FIG. 1. In FIG. 2, the high-pressure working fluid travels in parallel along fluid bus 110 to fluid expanders 105a and 105b. The fluid expanders 105a and 105b extract mechanical energy through the expansion process and the working fluid exits the expanders at low-pressure. The cooled working fluid travels along the fluid bus 110 to component heat exchangers 106a, 106b, and 106c to cool component modules 107a, 107b, and 107c. This configuration of fluid expanders 105, component heat exchangers 106, and component modules 107 can be repeated as denoted by enumeration 109. The low-pressure working fluid is routed back to recuperative heat exchanger 104 where it pre-cools the incoming high-pressure working fluid. Other embodiments can include a combination of series and parallel fluid expanders. An advantage of staging the fluid expanders in parallel is that there can be higher total fluid flow rates and cooling power.

FIG. 3 shows a schematic drawing of an expansion cooling system with more than one recuperative heat exchangers 104a and 104b. In this embodiment, the energy extracting fluid expanders 105a and 105b are arranged in parallel as is common in Collins or Claude liquefication cycles. This arrangement of several recuperative heat exchangers and fluid expanders may allow for lower temperature operation and partial liquefication of the working fluid. The working fluid is then routed via the fluid bus 110 to component heat exchangers 106. The FIG. 3 embodiment also includes an optional Joule-Thomson throttle 112 in addition to the fluid expanders 105. The Joule-Thomson throttle 112 may be used as a final stage of working fluid expansion in some designs for simplicity of construction.

FIG. 4 illustrates an embodiment of an expansion cooling system where the mechanical energy from fluid expanders 105 is used to affect an energy dissipation in dissipation components 111. The advantage of this embodiment is that a simple energy dissipation mechanism can be used to reduce overall system cost and complexity. In this embodiment, the dissipation component 111 is energetically coupled to fluid expander 105. In the FIG. 4 embodiment, the dissipation components 111a and 111b are arranged to be independent, but in other embodiments, these dissipation components may be arranged to be dependent, or a combination thereof. The energy dissipation component depends on the type of fluid expander employed in the cryogenic cooling system. For example, if a reciprocating piston expander is used as the fluid expander, then the dissipation component may be a brake that converts the energy of piston motion into heat at the brake.

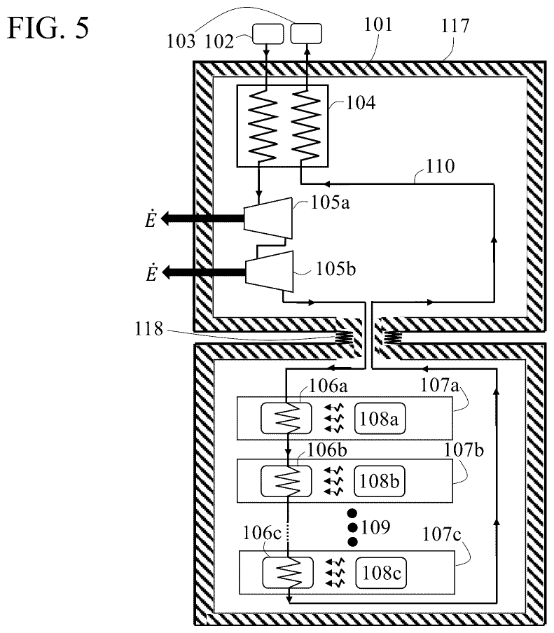

FIG. 5 is an embodiment of an expansion cooling system with a vibration isolator 118. The vibration isolator 118 may be a flexible bellows or other insulated transfer line. The vibration isolator 118 prevents any vibration generated by the fluid expanders 105a and 105b from being transferred to the computational components 108. It is preferable to keep the length of the vibration isolator 118 to a minimum to limit the parasitic heat losses to the ambient environment. The vibration isolator 118 on or within insulated housing 117 maintains insulation of fluid bus 110 and provides computational components 108 with point-of-use refrigeration and minimal vibrations.

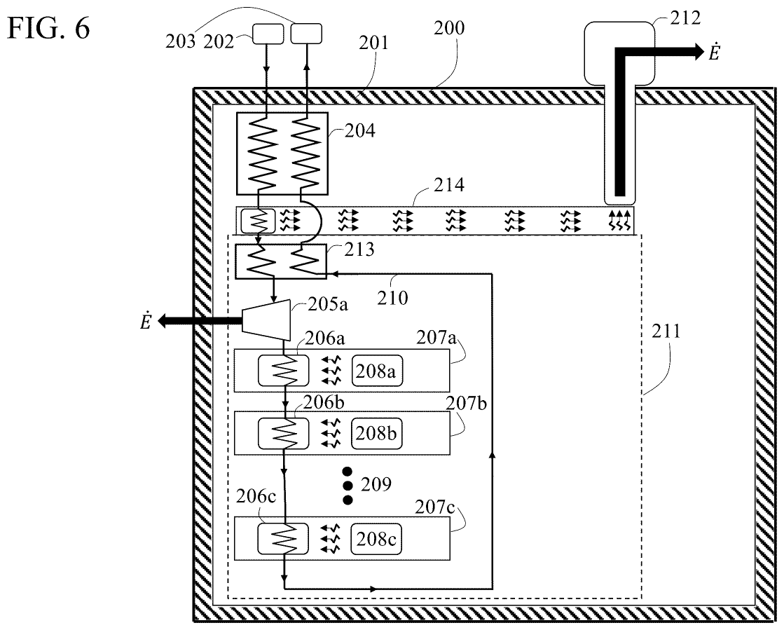

FIG. 6 is an embodiment of an expansion cooling system that combines a regenerative cryocooler stage 212. The regenerative cryocooler 212 may also be regarded as an expander in some embodiments. The regenerative cryocooler is mounted to the insulated housing 200 and thermally coupled to cryocooler heat exchanger 214 wherein cryocooler heat exchanger 214 is in the interior of the insulated housing. The cryocooler heat exchanger 214 may remove heat from the working fluid within the fluid bus 210. This cryocooler heat exchanger 214 may be a large plate of high conductivity metal such as copper that is in thermal contact with the cold end of the regenerative cryocooler 212. Cryocooler heat exchanger 214 may also be in thermal contact with a radiation shield 211. The radiation shield 211 is an additional layer of thermal insulation to thermally isolate the fluid bus 210 and computational components 208. This radiation shield may be made of a thermally conductive metal like copper. Recuperative heat exchanger 213 is used to recover cooling.

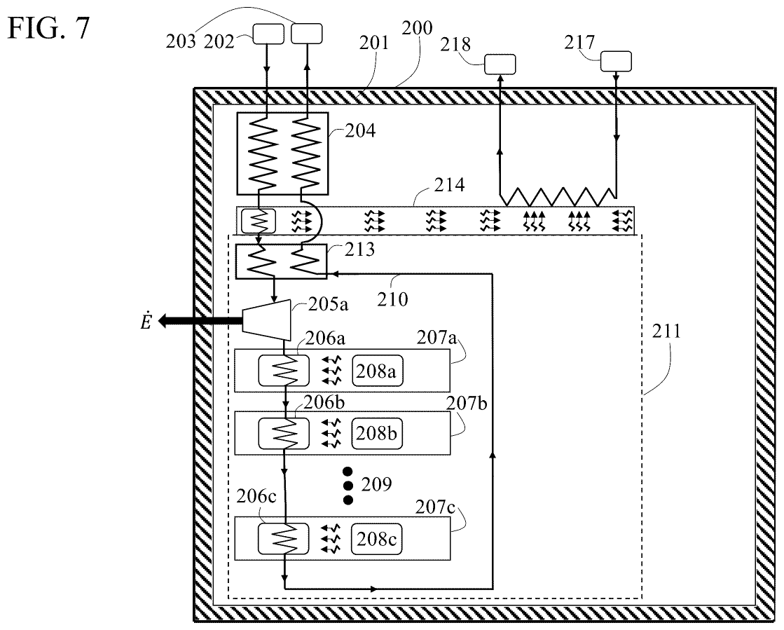

FIG. 7 is an embodiment of a dual fluid expansion cooling system for computational components where a secondary working fluid is circulated within the insulated housing 200 in addition to the primary working fluid. The secondary fluid enters the insulated housing through secondary inlet manifold 217 and exits at secondary outlet manifold 218. The secondary inlet manifold 217 may be at a temperature that is lower than the ambient temperature. For example, if the secondary fluid is liquid nitrogen, then the secondary inlet manifold may be at a temperature near 80 K. The secondary outlet manifold may also be at a temperature that is lower than the ambient temperature. The secondary fluid is thermally coupled to a secondary heat exchanger 214. The secondary heat exchanger may be a plate of high thermal conductivity metal such as copper. The secondary fluid may be liquid nitrogen or another cryogenic fluid. The advantage of using liquid nitrogen, for example, is that it is readily available in large quantities and generally inexpensive as compared with liquid helium.

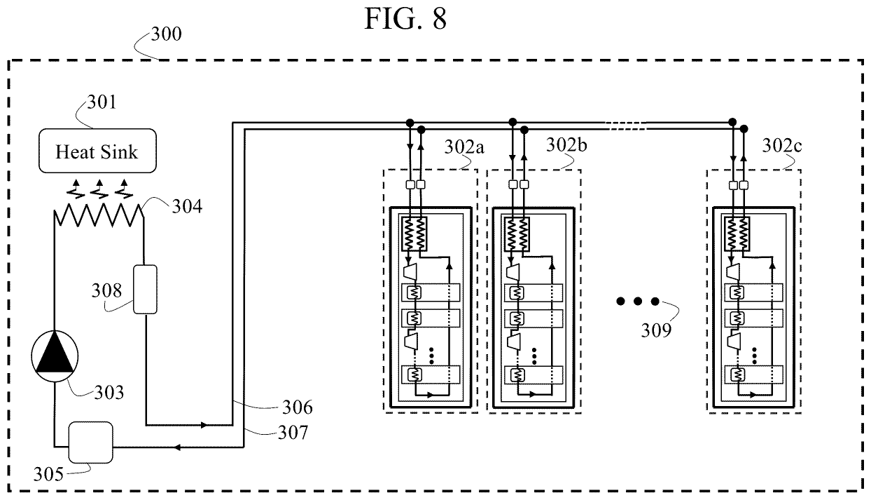

FIG. 8 is an embodiment of a set of expansion cooling systems 302 integrated into a cryogenic cooling system 300 for a computational facility. In this cryogenic cooling system 300, a set of fluid compressors 303 circulates and pressurizes the working fluid between the set of facility fluid supply lines 306 and the set of facility fluid return lines 307. The facility supply lines and facility return lines are at high pressure and low pressure, respectively. The set of facility supply lines and set of facility return lines are at a temperature that is near the ambient temperature. The facility fluid supply lines and facility fluid return lines are connected to the inlet manifolds and outlet manifolds of two or more expansion cooling systems 302. An example series type expansion cooling system configuration is shown within 302a, 302b, and 302c with additional systems possible as denoted by enumeration 309. The connection of multiple configurations of expansion cooling systems or multiple compression systems beyond that shown in FIGS. 1 through 7 are possible. After the working fluid is discharged from a set of fluid compressors 303 it passes through an aftercooler heat exchanger 304 that is thermally coupled to heat sink 301. Heat sink 301 can be the environment air, water, or another heat sink. A buffer tank 305 may be added to the primary supply line or primary return line to stabilize operation and store pressurized working fluid. Purification system 308 purifies the working fluid to remove condensable contaminants in the working fluid that may condense in the low temperature stages of the expansion cooling system. The purification system may be an oil removal system that collects any oil vapor carried by the working fluid from an oil-lubricated fluid compressor. The purification system may also be a molecular sieve or activated carbon that removes contaminants from the working fluid. The purification system may also be held at a cryogenic temperature, for example, liquid nitrogen temperature to remove additional contaminants.

The set of fluid compressors 303 may be comprised of several fluid compressors. These fluid compressors may be screw compressors, scroll compressors, turbine compressors, reciprocating piston compressors, or another type of fluid compressor. In some embodiments, these fluid compressors may be staged in series with intercooling heat sinks between compressor stages. Intercooling heat sinks may be advantageous to improve the efficiency of the set of fluid compressors. The fluid compressors may also be staged in parallel. Parallel staging of the fluid compressors allows for a higher flow rate of the working fluid. A combination of series and parallel staging may also be used.

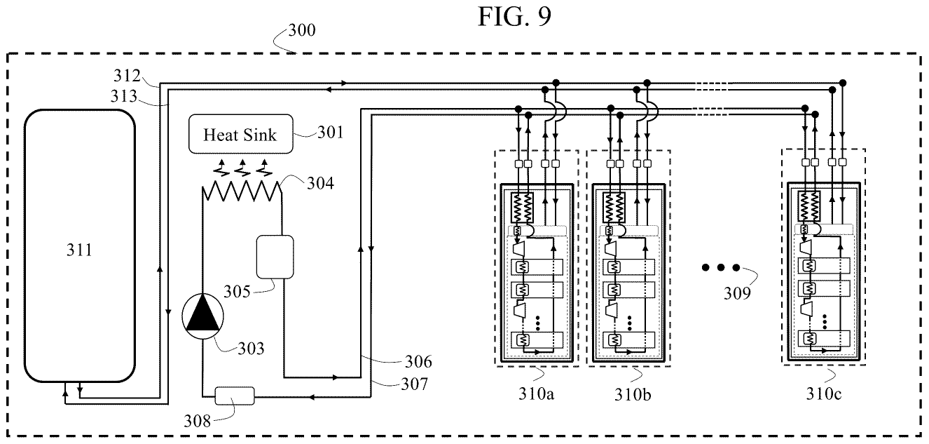

FIG. 9 is an embodiment of a computational facility 300 that uses both a primary and secondary fluid in the computational facility to the dual fluid expansion cooling system 310. The secondary fluid is circulated through the set of facility secondary fluid supply lines 312 and returned through the set of facility secondary fluid return lines 313. The secondary fluid may be liquid nitrogen or another cryogen such as liquid air. The secondary fluid source 311 may be a liquid nitrogen tank or a cryogenic storage dewar or a nitrogen liquefier. This multi-fluid cooling scheme can be extended from two-fluids seen in FIG. 9 to a plurality of fluids based on the requirements of the computational facility.

This type of expansion cooling architecture can be employed in low-temperature data center facilities. In these low-temperature data center facilities, the computer processors, computer memory, servers, and associated equipment require cooling at cryogenic temperatures of 100 K and below. In this application, the working fluid may be a gas, for example, nitrogen, air, or helium. The typical pressures in the set of facility fluid supply lines may be between 5-50 atmospheres and the typical pressures in the set of facility fluid return lines may be between 1-30 atmospheres.

While this specification contains many specific implementation details, these should not be construed as limitations on the scope of any disclosed subject matters or of what may be claimed, but rather as descriptions of features specific to particular implementations of particular disclosed subject matters. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations may be depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described components and systems can generally be integrated together in a single product or packaged into multiple products.

Each numerical value presented herein is contemplated to represent a minimum value or a maximum value in a range for a corresponding parameter. Accordingly, when added to the claims, the numerical value provides express support for claiming the range, which may lie above or below the numerical value, in accordance with the teachings herein. Every value between the minimum value and the maximum value within each numerical range presented herein (including in the figures), is contemplated and expressly supported herein, subject to the number of significant digits expressed in each particular range. Absent express inclusion in the claims, each numerical value presented herein is not to be considered limiting in any regard.

Unless expressly described elsewhere in this application, as used herein, when the term “substantially” or “about” is before a quantitative value, the present disclosure also includes the specific quantitative value itself, as well as, in various cases, a ±1%, ±2%, ±5%, and/or ±10% variation from the nominal value unless otherwise indicated or inferred.

Having described herein illustrative embodiments, persons of ordinary skill in the art will appreciate various other features and advantages of the disclosed subject matter apart from those specifically described above. It should therefore be understood that the foregoing is only illustrative of the principles of the disclosed subject matter, and that various modifications and additions, as well as all combinations and permutations of the various elements and components recited herein, can be made by those skilled in the art without departing from the spirit and scope of the disclosed subject matter. Accordingly, the appended claims shall not be limited by the particular features that have been shown and described, but shall be construed also to cover any obvious modifications and equivalents thereof.

### Listing of Drawing Elements

100 insulated housing
101 thermal insulation
102 inlet manifold
103 outlet manifold
104 recuperative heat exchanger
105 fluid expander
106 component heat exchanger
107 component module
108 computational component
109 enumeration
110 fluid bus
111 energy dissipation component
112 Joule-Thomson throttle
117 insulated housing with vibration isolation
118 vibration isolation component
200 insulated housing
201 thermal insulation
202 ambient temperature inlet manifold
203 ambient temperature outlet manifold
204 recuperative heat exchanger
205 fluid expander
206 component heat exchanger
207 component module
208 computational component
209 enumeration
210 fluid bus
211 radiation shield
212 cryocooler
213 recuperative heat exchanger
214 cryocooler heat exchanger
215 secondary fluid heat exchanger
217 secondary inlet manifold
218 secondary outlet manifold
300 cryogenic cooling system
301 heat sink
302 expansion cooling system
303 set of fluid compressors
304 aftercooler heat exchanger
305 buffer tank
306 set of facility fluid supply lines
307 set of facility fluid return lines
308 purification system
309 enumeration
310 dual fluid expansion cooling system
311 secondary fluid source
312 set of facility secondary fluid supply lines
313 set of facility secondary fluid return lines

What is claimed is:

1. A cryogenic cooling system for a computational facility, comprising:
a set of facility fluid supply lines at ambient temperature;
a set of facility fluid return lines at ambient temperature;
a set of fluid compressors that pressurize a working fluid between the set of facility fluid return lines and the set of facility fluid supply lines;
a set of aftercooler heat exchangers fluidically coupled to the set of facility fluid supply lines and thermally coupled to a heat sink;
a set of insulated housings wherein an interior of each insulated housing in the set of insulated housings is configured to accommodate a set of computational components, the computational components requiring cryogenic cooling;
an inlet manifold disposed at each insulated housing of the set of insulated housings, and configured to be connected to the set of facility fluid supply lines at ambient temperature;
an outlet manifold disposed at each insulated housing of the set of insulated housings, and configured to be connected to the set of facility fluid return lines at ambient temperature;
a fluid bus in the interior of each insulated housing of the set of insulated housings, configured to carry the working fluid between the inlet manifold and the outlet manifold;
a set of component heat exchangers fluidically coupled to the primary fluid bus and thermally coupled to the set of computational components; and
a set of energy extracting fluid expanders disposed at each insulated housing of the set of insulated housings and coupled to the primary fluid bus,
wherein the set of energy extracting fluid expanders are configured to cause cooling by expansion of the working fluid therein.

2. The cryogenic cooling system of claim 1, wherein the insulated housing interior is under a complete or partial vacuum.

3. The cryogenic cooling system of claim 1, wherein the insulated housing interior is filled or partially filled by a fluid.

4. The cryogenic cooling system of claim 1, wherein the set of energy extracting fluid expanders are reciprocating piston expanders, turbine-expanders, or other expanders that reduce fluid pressure to extract energy.

5. The cryogenic cooling system of claim 1, wherein the rate of cooling delivered to the computational components can be controlled by modifying the working fluid flow rate through the energy extracting fluid expanders and/or modifying the working fluid flow rate from the set of fluid compressors.

6. The cryogenic cooling system of claim 1, wherein the energy extracted by the set of energy extracting fluid expanders is transferred to the exterior of the insulated housing.

7. The cryogenic cooling system of claim 6, wherein the energy extracted is used to drive a compression process.

8. The cryogenic cooling system of claim 6, wherein the energy extracted is dissipated as heat to a heat sink.

9. The cryogenic cooling system of claim 1, wherein the set of energy extracting fluid expanders are staged in series or in parallel or in a combination thereof.

10. The cryogenic cooling system of claim 1, wherein a set of recuperative heat exchangers is configured to be connected to the fluid bus to recover heat between the outgoing return fluid and the incoming supply fluid.

11. The cryogenic cooling system of claim 1, wherein the computational components include quantum computers, single photon detectors, computer memory, CMOS processors, superconducting digital circuits, or a combination thereof.

12. The cryogenic cooling system of claim 1, wherein the heat sink that is thermally coupled to the aftercooler heat exchangers is ambient air, water, or other heat sink.

13. The cryogenic cooling system of claim 1, wherein the fluid compressor of the set of fluid compressors are rotary screw compressors, turbine compressors, reciprocating compressors, scroll compressors, or another fluid compressor type.

14. The cryogenic cooling system of claim 1, wherein the set of fluid compressors is staged in parallel, series, or a combination thereof.

15. The cryogenic cooling system of claim 1, wherein a cryocooler is disposed at each insulated housing of set of insulated housings to provide cooling to the fluid bus.

16. The cryogenic cooling system of claim 1, wherein a purification system is configured to be connected to the set of facility fluid supply lines or set of facility fluid return lines to remove contamination from the working fluid.

17. The cryogenic cooling system of claim 1, wherein a buffer tank is configured to be connected to the set of facility fluid supply lines or the set of facility fluid return lines.

18. The cryogenic cooling system for a computational facility of claim 1, further comprising:
a set of facility secondary fluid supply lines for supplying a secondary fluid;
a set of facility secondary fluid return lines for returning a secondary fluid;
a secondary inlet manifold disposed at each insulated housing of the set of insulated housings, wherein the secondary inlet manifold is configured to be connected to the set of facility secondary fluid supply lines;
a secondary outlet manifold disposed at each insulated housing of the set of insulated housings, wherein the secondary outlet manifold is configured to be connected to the set of facility secondary fluid return lines;
a secondary fluid bus in an interior of each insulated housing of the set of insulated housings configured to carry the secondary fluid between the secondary inlet manifold and secondary outlet manifold; and
a set of fluid heat exchangers fluidically coupled to the secondary fluid bus and thermally coupled to the primary fluid bus.

19. The cryogenic cooling system of claim 18, wherein the secondary fluid is a cryogenic liquid such as liquid nitrogen or liquid air, or any other cryogenic liquid that is supplied from a cryogenic liquid storage dewar.

20. The cryogenic cooling system of claim 19, wherein the cryogenic liquid storage dewar is supplied with the cryogenic liquid by a liquefier at the computational facility.
